(19) United States
(12) Patent Application Publication
(10) Pub. No.: US 2026/0142063 A1
(43) Pub. Date: May 21, 2026

(54) ELECTRONIC COMPONENT, MANUFACTURING METHOD THEREOF, AND THIN-FILM RESISTOR

(71) Applicant: TONG HSING ELECTRONIC INDUSTRIES, LTD., Taoyuan City (TW)

(72) Inventors: YAN-RU YANG, Taoyuan City (TW); JHIH-WEI LAI, Taoyuan City (TW); JIAN-YU SHIH, Taoyuan City (TW)

(21) Appl. No.: 19/008,587

(22) Filed: Jan. 2, 2025

(30) Foreign Application Priority Data
Nov. 21, 2024 (TW) 113144813

(51) Int. Cl. H01C 17/12; H01C 1/142; H01C 7/00; H01C 17/242; H05K 1/03; H05K 3/34

(52) U.S. Cl. CPC H01C 17/12; H01C 1/142; H01C 7/006; H01C 17/242; H05K 1/0306; H05K 3/3442

(57) ABSTRACT

An electronic component, a manufacturing method thereof, and a thin-film resistor are provided. The manufacturing method includes: forming a thru-hole in a ceramic substrate; forming a resistor film on the ceramic substrate; forming a metal layer on the ceramic substrate to cover a part of the resistor film and to be partially arranged in the thru-hole; forming a conductive structure on the metal layer, in which a part of the conductive structure located at one side of the ceramic substrate includes a first electrode, a second electrode, and a circuit, and another part of the conductive structure located at another side of the ceramic substrate has a third electrode electrically coupled to the first electrode, the second electrode, or the circuit; forming an insulating protection layer on another part of the resistor film uncovered by the metal layer; and forming an auxiliary soldering structure on the second electrode.

### CROSS-REFERENCE TO RELATED PATENT APPLICATION

This application claims the benefit of priority to Taiwan Patent Application No. 113144813, filed on Nov. 21, 2024. The entire content of the above identified application is incorporated herein by reference.

Some references, which may include patents, patent applications and various publications, may be cited and discussed in the description of this disclosure. The citation and/or discussion of such references is provided merely to clarify the description of the present disclosure and is not an admission that any such reference is “prior art” to the disclosure described herein. All references cited and discussed in this specification are incorporated herein by reference in their entireties and to the same extent as if each reference was individually incorporated by reference.

### FIELD OF THE DISCLOSURE

The present disclosure relates to an electronic component, a manufacturing method thereof, and a thin-film resistor, and more particularly to a manufacturing method of an electronic component having a resistor film and an electronic component having a resistor film.

### BACKGROUND OF THE DISCLOSURE

In a conventional electronic component having a thin-film resistor, the thin-film resistor is directly exposed in air, such that the thin-film resistor can fail to perform its intended function due to various environmental factors.

### SUMMARY OF THE DISCLOSURE

In response to the above-referenced technical inadequacies, the present disclosure provides an electronic component, a manufacturing method thereof, and a thin-film resistor for effectively improving on the malfunctioning issues of the thin-film resistor in conventional electronic components due to environmental factors.

In order to solve the above-mentioned problems, one of the technical aspects adopted by the present disclosure is to provide a manufacturing method of an electronic component. The manufacturing method includes: a thru-hole formation step, a resistor film formation step, a metal layer formation step, a conductive structure formation step, an insulating protection layer formation step, and an auxiliary soldering structure formation step. The thru-hole formation step is implemented by forming at least one thru-hole in a ceramic substrate. The at least one thru-hole penetrates through the ceramic substrate. The resistor film formation step is implemented by forming a resistor film on one side of the ceramic substrate. The metal layer formation step is implemented by forming a metal layer on the ceramic substrate. One part of the metal layer covers a part of the resistor film, and another part of the metal layer is formed on an inner wall defining the thru-hole. The conductive structure formation step is implemented by forming a conductive structure on the metal layer. The conductive structure includes a first part, a second part, and a conductive material. The first part is located at one side of the ceramic substrate and includes a first electrode, a second electrode, and at least one circuit. The second part is located at another side of the ceramic substrate and has a third electrode. The conductive material is arranged in the thru-hole. The third electrode is electrically coupled to the first electrode, the second electrode, or the at least one circuit through the conductive material. The insulating protection layer formation step is implemented by forming an insulating protection layer on another part of the resistor film that is not covered by the metal layer. The auxiliary soldering structure formation step is implemented by forming an auxiliary soldering structure on the second electrode. The auxiliary soldering structure is configured for allowing a chip to be mounted thereon.

In order to solve the above-mentioned problems, another one of the technical aspects adopted by the present disclosure is to provide an electronic component, which includes a ceramic substrate, a resistor film, a metal layer, a conductive material, a first electrode, a second electrode, a circuit, a third electrode, an insulating protection layer, and an auxiliary soldering structure. The ceramic substrate has at least one thru-hole that penetrates through the ceramic substrate. The resistor film is formed on one side of the ceramic substrate. The metal layer is formed on the ceramic substrate. One part of the metal layer covers a part of the resistor film, and another part of the metal layer is formed on an inner wall defining the at least one thru-hole. The conductive material is filled in the at least one thru-hole. The first electrode, a second electrode, and a circuit are formed on one side of the metal layer. The third electrode is formed on another side of the metal layer, and the third electrode is electrically coupled to the first electrode, the second electrode, or the circuit through the conductive material. The insulating protection layer is formed on another part of the resistor film that is not covered by the metal layer. The auxiliary soldering structure is formed on the second electrode and is configured for allowing a chip to be mounted thereon.

In order to solve the above-mentioned problems, yet another one of the technical aspects adopted by the present disclosure is to provide an electronic component, which includes a first ceramic substrate, a first conductive material, a second ceramic substrate, a second conductive material, a connection structure, a resistor film, a conductive structure, an insulating protection layer, and an auxiliary soldering structure. The first ceramic substrate has at least one first thru-hole that penetrates through the first ceramic substrate. The first conductive material is filled in the at least one first thru-hole. The second ceramic substrate has at least one second thru-hole that penetrates through the second ceramic substrate. The second conductive material is filled in the at least one second thru-hole. The connection structure connects the first ceramic substrate and the second ceramic substrate. The connection structure, the first material, and the second material are electrically coupled to each other. The resistor film is formed on one side of the first ceramic substrate away from the second ceramic substrate. The conductive structure includes a first part and a second part. The first part is formed on the one side of the first ceramic substrate and covers a part of the resistor film. The first part of the conductive structure includes a first electrode, a second electrode, and at least one circuit. The second part has a third electrode formed on one side of the second ceramic substrate away from the first ceramic substrate. The third electrode is electrically coupled to the first electrode, the second electrode, or the at least one circuit through the connection structure, the first conductive material, and the second conductive material. The insulating protection layer is formed on another part of the resistor film that is not covered by the metal layer. The auxiliary soldering structure is formed on the second electrode, and the auxiliary soldering structure is configured for allowing a chip to be mounted thereon.

In order to solve the above-mentioned problems, still yet another one of the technical aspects adopted by the present disclosure is to provide a thin-film resistor, which includes a ceramic substrate, a resistor film, a metal layer, a conductive material, a first electrode, a second electrode, a circuit, a third electrode, and an insulating protection layer. The ceramic substrate has at least one thru-hole that penetrates through the ceramic substrate. The resistor film is formed on one side of the ceramic substrate. The metal layer is formed on the ceramic substrate. One part of the metal layer covers a part of the resistor film, and another part of the metal layer is formed on an inner wall defining the at least one thru-hole. The conductive material is filled in the at least one thru-hole. The first electrode, a second electrode, and a circuit are formed on one side of the metal layer. The third electrode is formed on another side of the metal layer, and the third electrode is electrically coupled to the first electrode, the second electrode, or the circuit through the conductive material. The insulating protection layer is formed on another part of the resistor film that is not covered by the metal layer.

Therefore, the electronic component, the manufacturing method thereof, and the thin-film resistor of the present disclosure can be provided with the insulating protection layer for reducing a probability of failure of the resistor film and for preventing the resistor film from accidentally coming in contact with other conductors to generate a short circuit.

These and other aspects of the present disclosure will become apparent from the following description of the embodiment taken in conjunction with the following drawings and their captions, although variations and modifications therein may be affected without departing from the spirit and scope of the novel concepts of the disclosure.

### BRIEF DESCRIPTION OF THE DRAWINGS

The described embodiments may be better understood by reference to the following description and the accompanying drawings, in which:

FIG. 1 is a flowchart of a manufacturing method of an electronic component according to a first embodiment of the present disclosure;

FIG. 2 is a schematic cross-sectional view showing a metal layer formation step of the manufacturing method according to the present disclosure;

FIG. 3 is a schematic cross-sectional view showing a conductive structure formation step of the manufacturing method according to the present disclosure;

FIG. 4 is a schematic cross-sectional view showing an insulating protection layer formation step of the manufacturing method and showing a thin-film resistor according to the present disclosure;

FIG. 5 is a schematic cross-sectional view showing an auxiliary soldering structure formation step of the manufacturing method and showing the electronic component according to the first embodiment of the present disclosure;

FIG. 6 is a schematic cross-sectional view showing the electronic component provided with a chip assembled thereon according to the present disclosure;

FIG. 7 is a flowchart of the manufacturing method according to a second embodiment of the present disclosure;

FIG. 8 is a schematic cross-sectional view of the electronic component according to the second embodiment of the present disclosure; and

FIG. 9 is a schematic cross-sectional view of the electronic component according to a third embodiment of the present disclosure.

### DETAILED DESCRIPTION OF THE EXEMPLARY EMBODIMENTS

The present disclosure is more particularly described in the following examples that are intended as illustrative only since numerous modifications and variations therein will be apparent to those skilled in the art. Like numbers in the drawings indicate like components throughout the views. As used in the description herein and throughout the claims that follow, unless the context clearly dictates otherwise, the meaning of “a,” “an” and “the” includes plural reference, and the meaning of “in” includes “in” and “on.” Titles or subtitles can be used herein for the convenience of a reader, which shall have no influence on the scope of the present disclosure.

The terms used herein generally have their ordinary meanings in the art. In the case of conflict, the present document, including any definitions given herein, will prevail. The same thing can be expressed in more than one way. Alternative language and synonyms can be used for any term(s) discussed herein, and no special significance is to be placed upon whether a term is elaborated or discussed herein. A recital of one or more synonyms does not exclude the use of other synonyms. The use of examples anywhere in this specification including examples of any terms is illustrative only, and in no way limits the scope and meaning of the present disclosure or of any exemplified term. Likewise, the present disclosure is not limited to various embodiments given herein. Numbering terms such as “first,” “second” or “third” can be used to describe various components, signals or the like, which are for distinguishing one component/signal from another one only, and are not intended to, nor should be construed to impose any substantive limitations on the components, signals or the like.

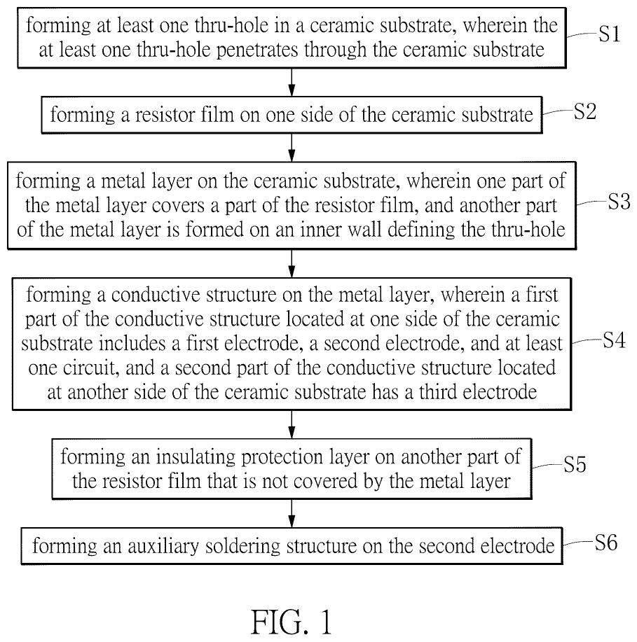

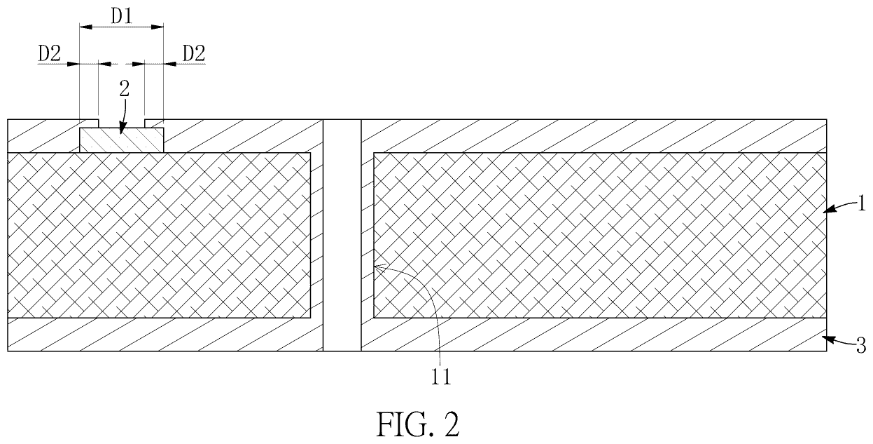

Referring to FIG. 1 to FIG. 5, FIG. 1 is a flowchart of a manufacturing method of an electronic component according to a first embodiment of the present disclosure, and FIG. 2 to FIG. 5 are schematic cross-sectional views showing a metal layer formation step, a conductive structure formation step, an insulating protection layer formation step, and an auxiliary soldering structure formation step of the manufacturing method according to the present disclosure.

The manufacturing method of the present disclosure includes the following steps.

A thru-hole formation step S1 is implemented by forming at least one thru-hole 11 in a ceramic substrate 1. The at least one thru-hole 11 penetrates through the ceramic substrate 1.

A resistor film formation step S2 is implemented by forming a resistor film 2 on one side of the ceramic substrate 1.

A metal layer formation step S3 is implemented by forming a metal layer 3 on the ceramic substrate 1. Moreover, one part of the metal layer 3 covers a part of the resistor film 2, and another part of the metal layer 3 is formed on an inner wall defining the thru-hole 11.

A conductive structure formation step S4 is implemented by forming a conductive structure 4 on the metal layer 3. Specifically, the conductive structure 4 includes a first part, a second part, and a conductive material 45. The first part of the conductive structure 4 is located at one side of the ceramic substrate 1 and includes a first electrode 41, a second electrode 42, and at least one circuit 43. The second part of the conductive structure 4 is located at another side of the ceramic substrate 1 and has a third electrode 44. The conductive material 45 is arranged in the thru-hole 11, and the third electrode 44 is electrically coupled to the first electrode 41, the second electrode 42, or the at least one circuit 43 through the conductive material 45.

An insulating protection layer formation step S5 is implemented by forming an insulating protection layer 5 on another part of the resistor film 2 that is not covered by the metal layer 2.

An auxiliary soldering structure formation step S6 is implemented by forming an auxiliary soldering structure 6 on the second electrode 42. The auxiliary soldering structure 6 is configured for allowing a chip to be mounted thereon.

In practice, the ceramic substrate 1 is a polished ceramic substrate 1 having a roughness (Ra) that can be less than 0.05 μm. In one of embodiments of the present disclosure, the main ingredients of the ceramic substrate 1 can be Al₂O₃ of 99.6%, Al₂O₃ of 96%, AlN, or Zirconia Toughened Aluminum (ZTA) according to practical requirements, and the present disclosure is not limited thereto.

In practice, as shown in FIG. 1 and FIG. 2, the thru-hole formation step S1 can be implemented by using a laser beam to process the ceramic substrate 1 so as to form the thru-hole 11 penetratingly formed in the ceramic substrate 1. In practice, an aperture of the thru-hole 11 can be designed according to a thickness of the ceramic substrate 1, but the present disclosure is not limited thereto. For example, if the thickness of the ceramic substrate 1 is within a range from 5 mil to 40 mil, a diameter of the thru-hole 11 can be within a range from 1 mil to 5 mil.

The resistor film formation step S2 can be implemented by using a photolithography process and a sputtering manner to form the resistor film 2 on the ceramic substrate 1. The resistor film 2 can be made of TaN, Ta₂N, or TaₓNₓ, and a thickness of the resistor film 2 can be within a range from 10 nm to 800 nm. In a process of forming the resistor film 2 on the ceramic substrate 1 in the sputtering manner, the TaN, Ta₂N, or TaₓNₓ can be sputtered by adjusting a flow rate of N₂. A specific pattern of the resistor film 2 can be designed according to practical requirements, and is not limited by the drawings of the present embodiment.

The metal layer formation step S3 can be implemented by using the photolithography process and the sputtering manner to form the metal layer 3 on the ceramic substrate 1. In the metal layer formation step S3, a part of the metal layer 3 can be formed in the thru-hole 11 by using a plated through hole (PTH) technology, and the metal layer 3 can be made of Ti or Cu.

As shown in FIG. 2, in a cross section of the ceramic substrate 1, the resistor film 2, and the metal layer 3 when the metal layer formation step S3 is implemented, two ends of the resistor film 2 covered by the metal layer 3 each have a length of at least 10 μm, thereby ensuring that the metal layer 3 and the first electrode 41 are connected to the resistor film 2 by an enough connection strength. In practice, since the metal layer 3 in formation process may have an offset of position, a ratio of a first width D1 and a second width D2 can be designed for ensuring that the metal layer 3 correctly covers the part of the resistor film 2.

In practice, the conductive structure formation step S4 can be implemented by using a direct plated copper (DPC) technology, a thin film ceramic (TFC) technology, or other technologies to form the conductive structure 4 on the metal layer 3. In one of embodiments of the present disclosure, the conductive material 45 in the thru-hole 11 can be same as a material of the first part and/or the second part of the conductive structure 4, but the present disclosure is not limited thereto. In practice, the first electrode 41 and the second electrode 42 can be respectively defined as a positive electrode and a negative electrode. Through the formation of the third electrode 44, the electronic component can be conveniently mounted on a circuit board by relevant personnel or apparatus. Positions and sizes of the first electrode 41, the second electrode 42, the at least one circuit 43, and the third electrode 44 can be designed according to practical requirements.

In the conductive structure formation step S4 provided by other embodiments of the present disclosure not shown in the drawings, the conductive material 45 can be formed on a part of the metal layer 3 that is located in the thru-hole 11, and then the first part and the second part of the conductive structure 4 are formed on other parts of the metal layer 3, such that the conductive material 45 can be made of a metal that is different from the first part and the second part of the conductive structure 4.

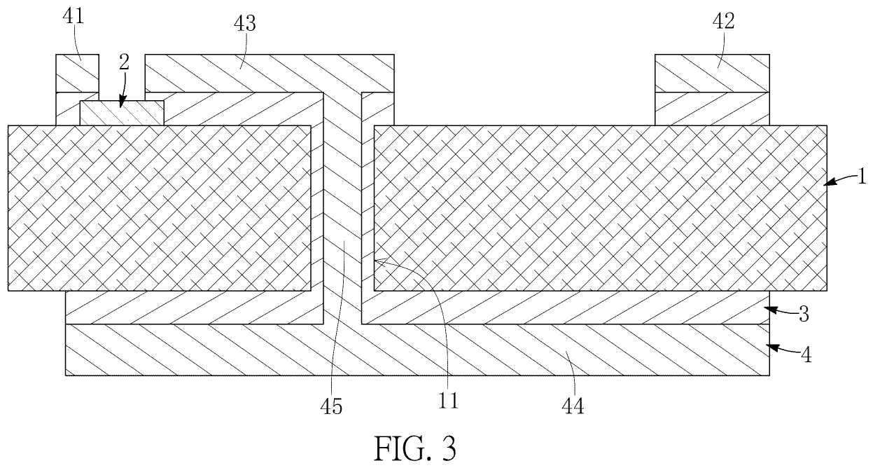

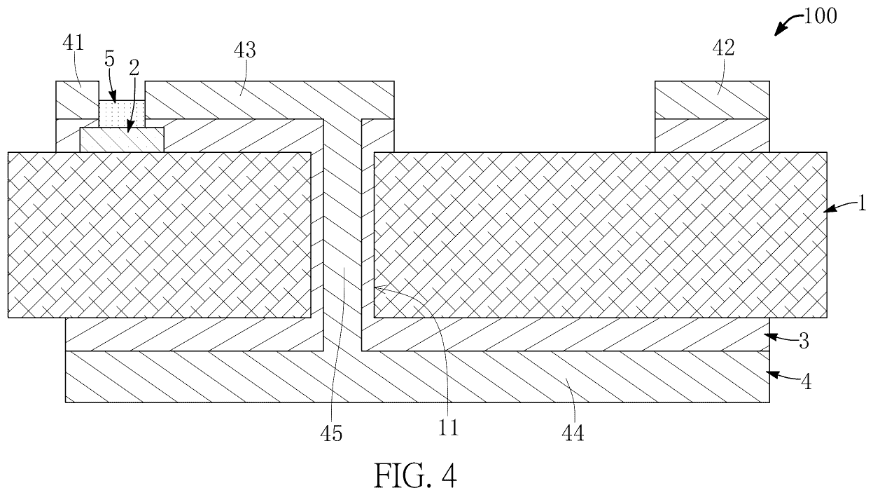

As shown in FIG. 3, in a cross section of a semi-finished product after the conductive structure formation step S4 is implemented, an upper side of the resistor film 2, an adjacent portion of the conductive structure 4 (e.g., the first electrode 41 and the at least one circuit 43), and the metal layer 3 jointly define a slot. As shown in FIG. 4, in a cross section of a semi-finished product after the insulating protection layer formation step S5 is implemented, the insulating protection layer 5 is filled in a part of the slot for enabling the resistor film 2 to be not exposed therefrom. In other embodiments of the present disclosure not shown in the drawings, the insulating protection layer 5 can be filled in an entirety of the slot; or, the insulating protection layer 5 can be filled in an entirety of the slot and can further protrude from the slot to cover a part of the first electrode 41 and a part of the at least one circuit 43.

In practice, as shown in FIG. 4, the insulating protection layer formation step S5 can be implemented by using the photolithography process to form the insulating protection layer 5 on the resistor film 2. Moreover, a thickness of the insulating protection layer 5 can be less than 10 μm, and the insulating protection layer 5 can be made of polyamic acid (PAA), polyimide (PI), polyamide (PA), polybenzoxazole (PBO), benzocyclobutene (BCB), epoxy, or SU-8 photoresist. The insulating protection layer 5 covers or is stacked on an entirety of the part of the resistor film 3 that is not covered by the metal layer 3, such that the resistor film 2 can be effectively protected to increase resistance of the resistor film 2 to moisture, chemicals and temperature changes, and the insulating protection layer 5 can be provided for preventing the resistor film 2 from accidentally coming in contact with other conductors to generate a short circuit. In addition, the insulating protection layer 5 can further provide a physical protection to the resistor film 2, thereby increasing resistance of the resistor film 2 to shaking, bending, and external impact.

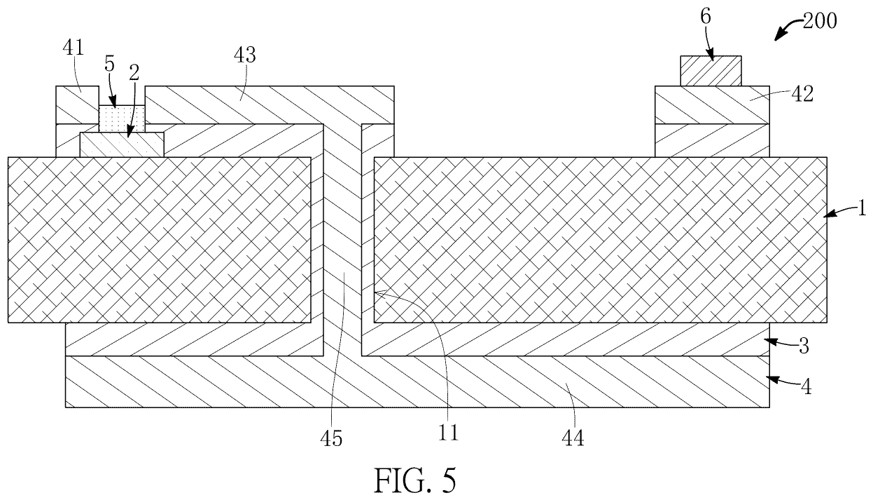

In practice, as shown in FIG. 5, the auxiliary soldering structure formation step S6 can be implemented by using an evaporation manner to form the auxiliary soldering structure 6 on the second electrode 42. The auxiliary soldering structure 6 can be made of Au—Sn alloy, a thickness of the auxiliary soldering structure can be within a range from 2 μm to 6 μm, and the auxiliary soldering structure 6 can have a weight percentage of Au that is within a range from 65% to 80%.

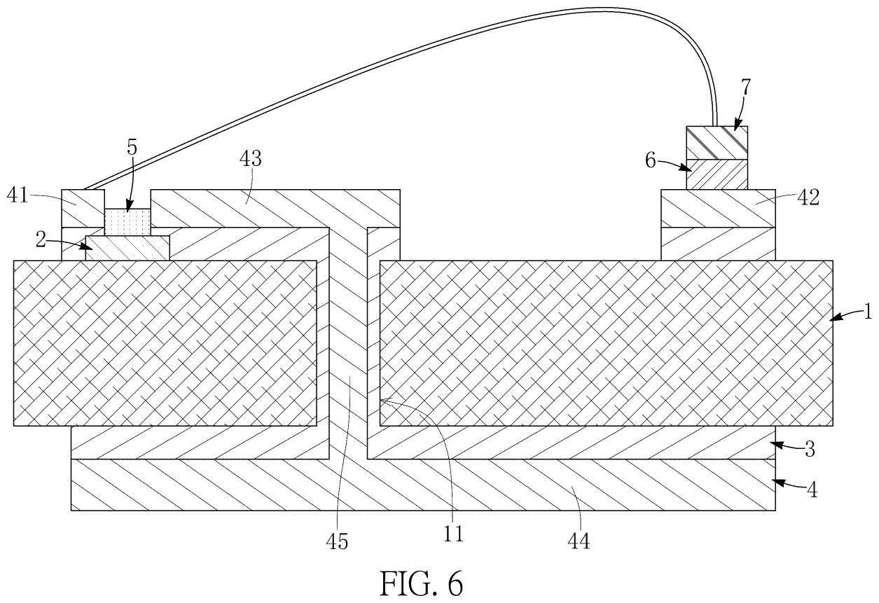

Referring to FIG. 1, FIG. 5, and FIG. 6, FIG. 6 is a schematic cross-sectional view showing the electronic component provided with a chip assembled thereon according to the present disclosure. In one of embodiments of the present disclosure, the manufacturing method further includes a chip assembling step after the auxiliary soldering structure formation step S6 is implemented. The chip assembling step is implemented by assembling a chip 7 onto the auxiliary soldering structure 6 and electrically connecting the chip 7 to the first electrode 41 (in a wire bonding manner). For example, the chip 7 can be a light emitting diode (LED) or a power chip, but the present disclosure is not limited thereto.

Referring to FIG. 4 and FIG. 5, FIG. 4 is a schematic cross-sectional view showing a thin-film resistor according to the present disclosure, and FIG. 5 is a schematic cross-sectional view showing the electronic component according to the first embodiment of the present disclosure. The thin-film resistor 100 and the electronic component 200 in the present disclosure can be manufactured by implementing the manufacturing method of the present embodiment, but the present disclosure is not limited thereto. As shown in FIG. 4, the thin-film resistor 100 in the present embodiment includes a ceramic substrate 1, a resistor film 2, a metal layer 3, a first electrode 41, a second electrode 42, a circuit 43, a third electrode 44, a conductive material 45, and an insulating protection layer 5. As shown in FIG. 4, the electronic component 200 in the present embodiment includes a ceramic substrate 1, a resistor film 2, a metal layer 3, a first electrode 41, a second electrode 42, a circuit 43, a third electrode 44, a conductive material 45, an insulating protection layer 5, and an auxiliary soldering structure 6. The description of the above components of the thin-film resistor 100 and the electronic component 200 are similar to the above description of the manufacturing method, and will be omitted herein for the sake of brevity.

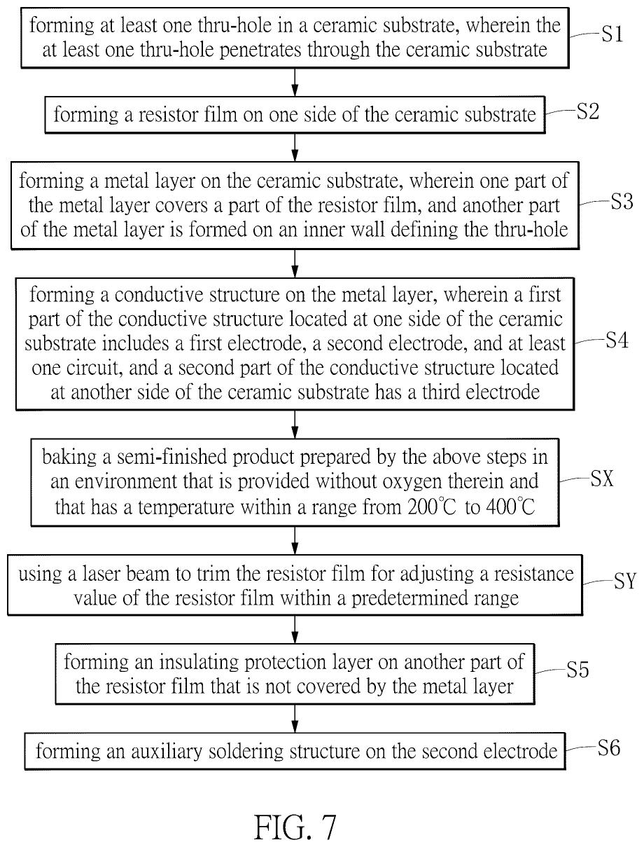

Referring to FIG. 5 and FIG. 7, FIG. 7 is a flowchart of the manufacturing method according to a second embodiment of the present disclosure. The main different features between the first and second embodiments are described as follows. The manufacturing method of the present embodiment further includes the followings steps between the conductive structure formation step S4 and the insulating protection layer formation step S5.

The conductive structure formation step S4 is implemented to manufacture a semi-finished product, and an annealing step SX is implemented by baking the semi-finished product in an environment that is provided without oxygen therein and that has a temperature within a range from 200° C. to 400° C.

A laser trimming step SY is implemented by using a laser beam to trim the resistor film 2 for adjusting a resistance value of the resistor film 2 within a predetermined range.

Through the annealing step SX, the resistance value of the resistor film 2 can be stable, and a range of the resistance value of the resistor film 2 can be reduced. For example, the resistance value of the resistor film 2 is within a range from 9 ohm to 12 ohm before the annealing step SX is implemented, and the resistance value of the resistor film 2 can be reduced to be within a range from 8.4 ohm to 8.5 ohm after the annealing step SX is implemented.

The laser trimming step SY can be implemented by using a UV laser beam or a green laser beam to trim the resistor film 2 for adjusting the resistance value of the resistor film 2. In practice, an error range of the resistance value of the resistor film 2 can be controlled for enabling the resistance value to be within ±1% of the predetermined range through the laser trimming step SY.

It should be noted that the manufacturing method of the first embodiment can further include one of the annealing step SX and the laser trimming step SY to become another embodiment.

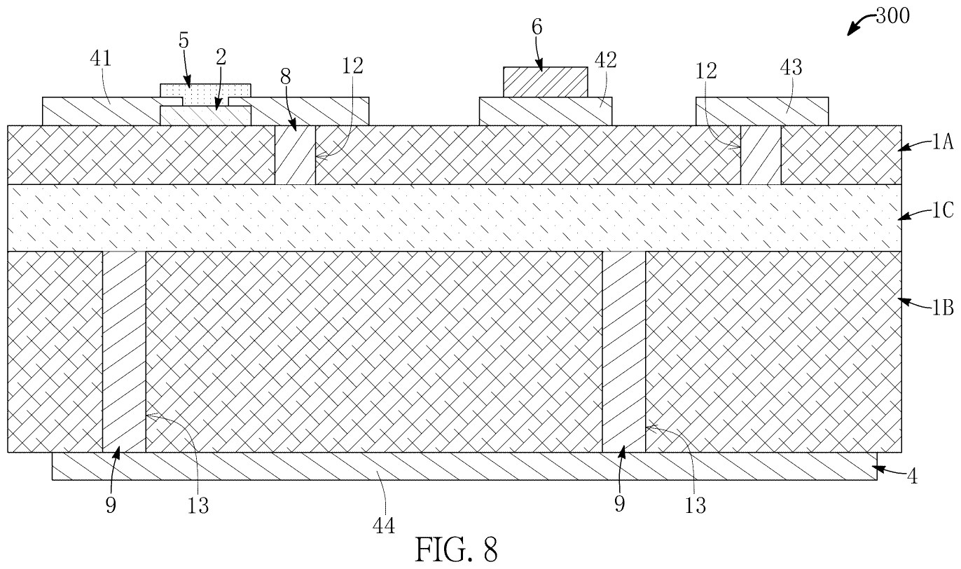

Referring to FIG. 8, FIG. 8 is a schematic cross-sectional view of the electronic component according to the second embodiment of the present disclosure. The electronic component 300 in the present embodiment includes a first ceramic substrate 1A, a second ceramic substrate 1B, a connection structure 1C, a resistor film 2, a conductive structure 4, an insulating protection layer 5, and an auxiliary soldering structure 6.

The first ceramic substrate 1A has a plurality of first thru-holes 12, and each of the first thru-holes 12 penetrates through the first ceramic substrate 1A. The second ceramic substrate 1B has a plurality of second thru-holes 13, and each of the second thru-holes 13 penetrates through the second ceramic substrate 1B. The connection structure 1C connects the first ceramic substrate 1A and the second ceramic substrate 1B. The connection structure 1C can be metallic paint (e.g., silver glue) according to practical requirements, and the present disclosure is not limited thereto. The connection structure 1C, a first conductive material 8 arranged in the first thru-holes 12, and a second conductive material 9 arranged in the second thru-holes 13 are electrically coupled to each other. The connection structure 1C, the first conductive material 8, and the second conductive material 9 can be made of a same material or different materials.

The resistor film 2 is formed on one side of the ceramic substrate 1A away from the second ceramic substrate 1B. The conductive structure 4 includes a first part and a second part. The first part of the conductive structure 4 is formed on the one side of the first ceramic substrate 1A and covers a part of the resistor film 2, and the first part of the conductive structure 4 includes a first electrode 41, a second electrode 42, and at least one circuit 43. The second part of the conductive structure 4 has a third electrode 44 formed on one side of the second ceramic substrate 1B away from the first ceramic substrate 1A. The third electrode 44 is electrically coupled to the first electrode 41, the second electrode 42, or the at least one circuit 43 through the connection structure 1C, the first conductive material 8, and the second conductive material 9. The description of the resistor film 2, the insulating protection layer 5, and the auxiliary soldering structure 6 are similar to the description of the above embodiment, and will be omitted herein for the sake of brevity. In practice, the first part of the conductive structure 4 and the second part of the conductive structure 4 (i.e., the third electrode 44) can be made of a same material or different materials.

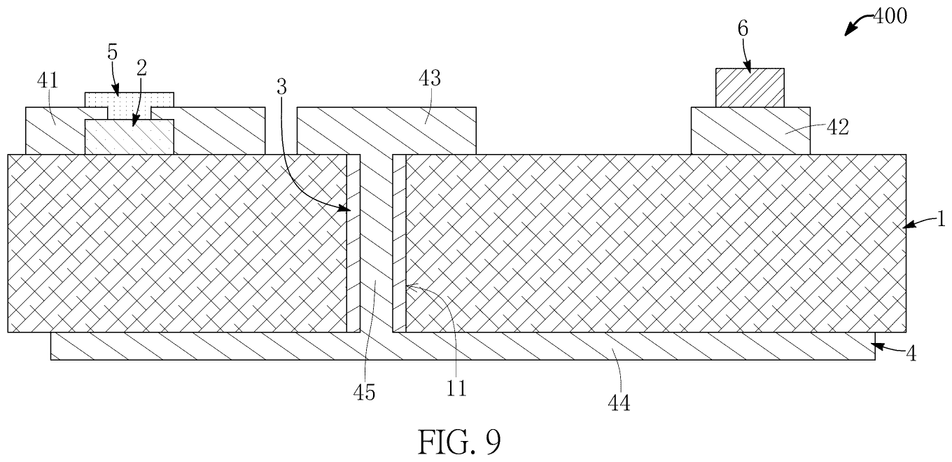

Referring to FIG. 9, FIG. 9 is a schematic cross-sectional view of the electronic component according to a third embodiment of the present disclosure. The electronic component 400 in the present embodiment includes a ceramic substrate 1, a resistor film 2, a metal layer 3, a first electrode 41, a second electrode 42, a circuit 43, a third electrode 44, a conductive material 45, an insulating protection layer 5, and an auxiliary soldering structure 6. The main different features between the electronic component 400 provided by the present embodiment and the electronic component 200 shown in FIG. 5 are described as follows. In the present embodiment, the metal layer 3 is only formed in the thru-hole 11 and is not formed on two opposite sides of the ceramic substrate 1, and the part of the resistor film 2 is covered by the conductive structure 4 (e.g., the first electrode 41). The description of the ceramic substrate 1, the resistor film 2, the metal layer 3, the first electrode 41, the second electrode 42, the circuit 43, the third electrode 44, the conductive material 45, the insulating protection layer 5, and the auxiliary soldering structure 6 are similar to the description of the above embodiment, and will be omitted herein for the sake of brevity.

In conclusion, the electronic component, the manufacturing method thereof, and the thin-film resistor of the present disclosure can be provided with the resistor film partially covered by the metal layer or the conductive structure, and the insulating protection layer is formed on one side of the resistor film, thereby effectively increasing the service life and reliability of the resistor film.

The foregoing description of the exemplary embodiments of the disclosure has been presented only for the purposes of illustration and description and is not intended to be exhaustive or to limit the disclosure to the precise forms disclosed. Many modifications and variations are possible in light of the above teaching.

The embodiments were chosen and described in order to explain the principles of the disclosure and their practical application so as to enable others skilled in the art to utilize the disclosure and various embodiments and with various modifications as are suited to the particular use contemplated. Alternative embodiments will become apparent to those skilled in the art to which the present disclosure pertains without departing from its spirit and scope.

What is claimed is:

1. A manufacturing method of an electronic component, comprising:
a thru-hole formation step implemented by forming at least one thru-hole in a ceramic substrate, wherein the at least one thru-hole penetrates through the ceramic substrate;
a resistor film formation step implemented by forming a resistor film on one side of the ceramic substrate;
a metal layer formation step implemented by forming a metal layer on the ceramic substrate, wherein one part of the metal layer covers a part of the resistor film, and another part of the metal layer is formed on an inner wall defining the thru-hole;
a conductive structure formation step implemented by forming a conductive structure on the metal layer, wherein the conductive structure includes:
a first part located at one side of the ceramic substrate and including a first electrode, a second electrode, and at least one circuit;
a second part located at another side of the ceramic substrate and having a third electrode; and
a conductive material arranged in the thru-hole, wherein the third electrode is electrically coupled to the first electrode, the second electrode, or the at least one circuit through the conductive material;
an insulating protection layer formation step implemented by forming an insulating protection layer on another part of the resistor film that is not covered by the metal layer; and
an auxiliary soldering structure formation step implemented by forming an auxiliary soldering structure on the second electrode, wherein the auxiliary soldering structure is configured for allowing a chip to be mounted thereon.

2. The manufacturing method according to claim 1, wherein, in a cross section of the ceramic substrate, the resistor film, and the metal layer when the metal layer formation step is implemented, two ends of the resistor film covered by the metal layer each have a length of at least 10 μm.

3. The manufacturing method according to claim 1, wherein a thickness of the insulating protection layer is less than 10 μm, and the insulating protection layer is made of polyamic acid (PAA), polyimide (PI), polyamide (PA), polybenzoxazole (PBO), benzocyclobutene (BCB), epoxy, or SU-8 photoresist.

4. The manufacturing method according to claim 1, wherein the resistor film is made of TaN, Ta₂N, or TaₓNₓ, and a thickness of the resistor film is within a range from 10 nm to 800 nm.

5. The manufacturing method according to claim 1, wherein the auxiliary soldering structure is made of Au—Sn alloy, a thickness of the auxiliary soldering structure is within a range from 2 μm to 6 μm, and the auxiliary soldering structure has a weight percentage of Au that is within a range from 65% to 80%.

6. The manufacturing method according to claim 1, further comprising an annealing step between the conductive structure formation step and the insulating protection layer formation step, wherein the conductive structure formation step is implemented to manufacture a semi-finished product, and wherein the annealing step is implemented by baking the semi-finished product in an environment that is provided without oxygen therein and that has a temperature within a range from 200° C. to 400° C.

7. The manufacturing method according to claim 6, further comprising a laser trimming step between the annealing step and the insulating protection layer formation step, wherein the laser trimming step is implemented by using a laser beam to trim the resistor film for adjusting a resistance value of the resistor film within a predetermined range.

8. An electronic component, comprising:
a ceramic substrate having at least one thru-hole that penetrates through the ceramic substrate;
a resistor film formed on one side of the ceramic substrate;
a metal layer formed on the ceramic substrate, wherein one part of the metal layer covers a part of the resistor film, and another part of the metal layer is formed on an inner wall defining the at least one thru-hole;
a conductive material filled in the at least one thru-hole;
a first electrode, a second electrode, and a circuit that are formed on one side of the metal layer;
a third electrode formed on another side of the metal layer, wherein the third electrode is electrically coupled to the first electrode, the second electrode, or the circuit through the conductive material;
an insulating protection layer formed on another part of the resistor film that is not covered by the metal layer; and
an auxiliary soldering structure formed on the second electrode and configured for allowing a chip to be mounted thereon.

9. The electronic component according to claim 8, wherein, in a cross section of the ceramic substrate, the resistor film, and the metal layer, two ends of the resistor film covered by the metal layer each have a length of at least 10 μm.

10. The electronic component according to claim 8, wherein a thickness of the insulating protection layer is less than 10 μm, and the insulating protection layer is made of polyamic acid (PAA), polyimide (PI), polyamide (PA), polybenzoxazole (PBO), benzocyclobutene (BCB), epoxy, or SU-8 photoresist.

11. The electronic component according to claim 8, wherein the resistor film is made of TaN, Ta₂N, or TaₓNₓ, and a thickness of the resistor film is within a range from 10 nm to 800 nm.

12. The electronic component according to claim 8, wherein the auxiliary soldering structure is made of Au—Sn alloy, a thickness of the auxiliary soldering structure is within a range from 2 μm to 6 μm, and the auxiliary soldering structure has a weight percentage of Au that is within a range from 65% to 80%.

13. The electronic component according to claim 8, wherein a material of any one of the first electrode, the second electrode, and the third electrode is different from the conductive material, and any one of the first electrode, the second electrode, and the third electrode is made of at least one of titanium, platinum, or gold.

14. An electronic component, comprising:
a first ceramic substrate having at least one first thru-hole that penetrates through the first ceramic substrate;
a first conductive material filled in the at least one first thru-hole;
a second ceramic substrate having at least one second thru-hole that penetrates through the second ceramic substrate;
a second conductive material filled in the at least one second thru-hole;
a connection structure that connects the first ceramic substrate and the second ceramic substrate, wherein the connection structure, the first material, and the second material are electrically coupled to each other;
a resistor film formed on one side of the first ceramic substrate away from the second ceramic substrate;
a conductive structure including:
a first part formed on the one side of the first ceramic substrate and covering a part of the resistor film, wherein the first part of the conductive structure includes a first electrode, a second electrode, and at least one circuit; and
a second part having a third electrode formed on one side of the second ceramic substrate away from the first ceramic substrate, wherein the third electrode is electrically coupled to the first electrode, the second electrode, or the at least one circuit through the connection structure, the first conductive material, and the second conductive material;
an insulating protection layer formed on another part of the resistor film that is not covered by the metal layer; and
an auxiliary soldering structure formed on the second electrode, wherein the auxiliary soldering structure is configured for allowing a chip to be mounted thereon.

15. A thin-film resistor, comprising:
a ceramic substrate having at least one thru-hole that penetrates through the ceramic substrate;
a resistor film formed on one side of the ceramic substrate;
a metal layer formed on the ceramic substrate, wherein one part of the metal layer covers a part of the resistor film, and another part of the metal layer is formed on an inner wall defining the at least one thru-hole;
a conductive material filled in the at least one thru-hole;
a first electrode, a second electrode, and a circuit that are formed on one side of the metal layer;
a third electrode formed on another side of the metal layer, wherein the third electrode is electrically coupled to the first electrode, the second electrode, or the circuit through the conductive material; and
an insulating protection layer formed on another part of the resistor film that is not covered by the metal layer.

16. The thin-film resistor according to claim 15, wherein, in a cross section of the ceramic substrate, the resistor film, and the metal layer, two ends of the resistor film covered by the metal layer each have a length of at least 10 μm.

17. The thin-film resistor according to claim 15, wherein a thickness of the insulating protection layer is less than 10 μm, and the insulating protection layer is made of polyamic acid (PAA), polyimide (PI), polyamide (PA), polybenzoxazole (PBO), benzocyclobutene (BCB), epoxy, or SU-8 photoresist.

18. The thin-film resistor according to claim 15, wherein the resistor film is made of TaN, Ta₂N, or TaₓNₓ, and a thickness of the resistor film is within a range from 10 nm to 800 nm.

19. The thin-film resistor according to claim 15, wherein a material of any one of the first electrode, the second electrode, and the third electrode is different from the conductive material, and any one of the first electrode, the second electrode, and the third electrode is made of at least one of titanium, platinum, or gold.
